(19) United States
(12) Patent Application Publication
(10) Pub. No.: US 2024/0128665 A1
(43) Pub. Date: Apr. 18, 2024

(54) FLEXIBLE CONNECTING STRUCTURE

(71) Applicant: Min Di Consultants Ltd., Hsinchu City (TW)

(72) Inventor: Chi-Di LEE, Hsinchu City (TW)

(21) Appl. No.: 17/966,073

(22) Filed: Oct. 14, 2022

(51) Int. Cl. H01R 12/61; H01R 12/65; H01R 12/70; H01R 12/72; H01R 31/06; H05K 1/18

(52) U.S. Cl. CPC H01R 12/613; H01R 12/65; H01R 12/7082; H01R 12/72; H01R 31/06; H05K 1/189; H05K 2201/09236; H05K 2201/094; H05K 2201/09409; H05K 2201/09609; H05K 2201/10189; H05K 2201/10234

(57) ABSTRACT

A flexible connecting structure comprises a first circuit board and a second circuit board. The second circuit board is configured on a bottom of the first circuit hoard. A plurality of first signal traces configured longitudinally on the first circuit board. A plurality of second signal traces configured longitudinally on the second circuit board. A first end of the first circuit board and a first end of the second circuit board is fixed with each other through a plurality of metal balls, and a second end of the second circuit board floats, deflectable up and down.

### BACKGROUND

### Technical Field

The present invention relates to a connecting structure, especially relates to a flexible connecting structure for transmitting a plurality of signals between electronic devices.

### Description of Related Art

FIG. 1 shows a prior art

U.S. Pat. No. 7,950,953 disclosed a multicore cable connector, the multicore cable connector 1 includes a cable fixing member 2, an aggregate cable 3 fixed in the cable fixing member 2, an aligning plate 4 for aligning the signal lines included in the aggregate cable 3 and a substrate 5 conductively connected with the signal lines of the aggregate cable 3.

The aggregate cable 3 includes a plurality of single cables each having two signal lines 312. The aggregate cable 3 further includes conductive drain wires 32 arranged along the outer periphery of a plurality of the single cables 31.

The substrate 5 has a front surface 51 and a back surface 52, each formed with a wiring pattern 53. An end of each wiring pattern 53 is formed with a land 54 making up a contact point with a socket (not shown) to be fitted with the connector 1, and the other end of each wiring pattern 53 is formed with a signal line mounting unit 55 making up a contact point with the signal lines 312 and a drain wire mounting unit 56 making up a contact point with the drain wire 32.

The disadvantage for the prior art is the plurality of cables used as the partial structure of the connector which is bulky and adverse to minimizing the connector between electronic devices.

### BRIEF DESCRIPTION OF THE DRAWINGS

FIG. 1 shows a prior art.

FIGS. 2-3 show a first embodiment according to the present invention.

FIG. 4 shows a first application for the first embodiment according to the present invention.

FIGS. 5-8 show a second application for the first embodiment according to the present invention.

FIGS. 9-11 show a third application for the first embodiment according to the present invention.

FIGS. 12-15, 16A and 16B show a second embodiment according to the present invention.

FIGS. 17A, 17B, 18A and 18B show an application for the second embodiment according to the present invention.

FIG. 19 shows a third embodiment according to the present invention.

FIGS. 20-21 show an application for the third embodiment according to the present invention.

FIG. 22 shows a fourth embodiment according to the present invention.

FIGS. 23-24 show an application for the fourth embodiment according to the present invention.

FIG. 25 shows a fifth embodiment according to the present invention.

FIGS. 26-27 show an application for the fifth embodiment according to the present invention.

FIG. 28 shows a sixth embodiment according to the present invention.

FIGS. 29-30 show an application for the sixth embodiment according to the present invention.

FIG. 31 shows a seventh embodiment according to the present invention.

FIGS. 32-35 show an application for the seventh embodiment according to the present invention.

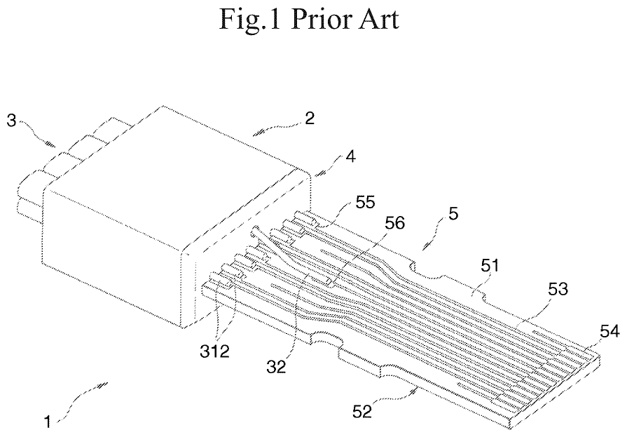

### DETAILED DESCRIPTION OF THE INVENTION

The present invention relates to a connecting structure for transmitting a plurality of signals between electronic devices. For example, a connector for transmitting signals between a mother board and an Electro-Optical Circuit Board (EOCB).

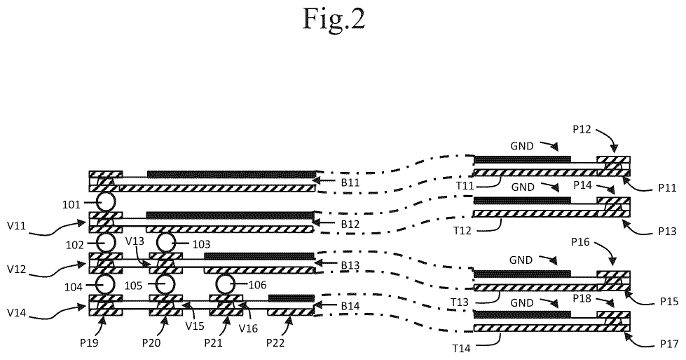

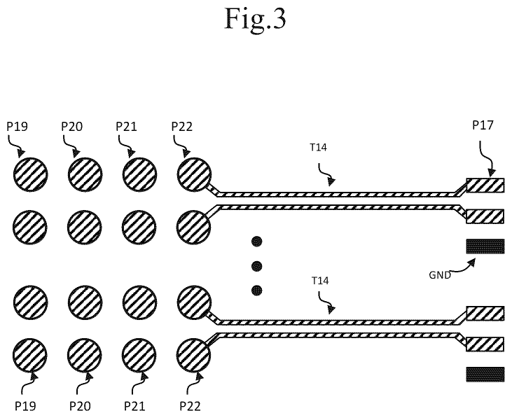

FIGS. 2-3 shows a first embodiment according to the present invention.

FIG. 2 shows a section view of the flexible connecting structure. The flexible connecting structure comprises: a first circuit board B11, and a plurality of first signal traces T11 longitudinally configured on a bottom surface of the first circuit board B11. A plurality of first metal balls 101 are configured on a left bottom of the first circuit board B11. Each first metal ball 101 is electrically coupled with a corresponding first signal trace T11.

A plurality of first metal pads P11 are configured on a right bottom surface of the first circuit board B11. Each first metal pad P11 is electrically coupled with a corresponding first signal trace T11. A plurality of second metal pads P12 are configured on a right top of the first circuit board B11. Each second metal pad P12 is electrically coupled with a corresponding first metal pad P11 through a corresponding metal via configured between them. A ground metal GND is configured on a top surface of the first circuit board B11.

A second circuit board B12 is configured on a bottom side of the first circuit board B11. A plurality of first metal vias V11 are configured at a left end of the second circuit board B12. Each first metal via V11 is electrically coupled with a corresponding first signal trace T11 through a corresponding first metal ball 101 and a metal pad configured between them. A plurality of second signal traces T12 are longitudinally configured on a bottom of the second circuit board B12. A plurality of third metal pads P13 are configured on a right bottom of the second circuit board B12. Each third metal pad P13 is electrically coupled with a corresponding second signal trace T12. A plurality of fourth metal pads P14 are configured on a right top of the second circuit board B12. Each fourth metal pad P14 is electrically coupled with a corresponding third metal pad P13 through a corresponding metal via configured between them. A ground metal GND is configured on a top surface of the second circuit board B12.

The left end of the first circuit board B11 and the left end of the second circuit board B12 are fixed with each other through a plurality of first metal balls 101. The right end of the first circuit board B11 floats up and down, and the right end of the second circuit board B12 floats, deflectable up and down.

A third circuit board B13 is configured on a bottom side of the second circuit board B12. A plurality of second metal vias V12 and third metal vias V13 are configured at a left end of the third circuit board B13. Each second metal via V12 is aligned with and electrically coupled with a corresponding first metal via V11 through a corresponding second metal ball 102 configured between them, and each third metal via V13 is electrically coupled with a corresponding second signal trace T12 through a corresponding third metal ball 103 configured between them. Each second metal ball 102 is electrically coupled with a corresponding first metal via V11 through a metal pad configured between them. Each third metal ball 103 is electrically coupled with a corresponding second signal trace T12. A plurality of fifth metal pads P15 are configured on a right bottom of the third circuit board B13. Each fifth metal pad P15 is electrically coupled with a corresponding third signal trace T13. A plurality of sixth metal pads P16 are configured on the right top of the third circuit board B13. Each sixth metal pad P16 is electrically coupled with a corresponding fifth metal pad P15 through a corresponding metal via configured between them. A ground metal GND is configured on a top surface of the third circuit board B13.

The left end of the second circuit board B12 and the left end of the third circuit board B13 are fixed with each other through a plurality of second metal balls 102 and third metal balls 103, and the right end of the third circuit board B13 floats, deflectable up and down. A fourth circuit board B14 is configured on a bottom side of the third circuit board B13. A plurality of fourth metal vias V14, fifth metal vias V15, and sixth metal vias V16 are configured at a left end of the fourth circuit board B14. Each fourth metal via V14 is aligned with and electrically coupled with a corresponding second metal via V12 through a corresponding fourth metal ball 104 configured between them. Each fifth metal via V15 is aligned with and electrically coupled with a corresponding third metal via V13 through a corresponding fifth metal ball 105 configured between them. Each sixth metal via V16 is electrically coupled with a corresponding third signal trace T13 through a corresponding sixth metal ball 106 and a metal pad configured between them. Each fourth metal ball 104 is electrically coupled with a corresponding second metal via V12 through a metal pad configured between them. Each fifth metal ball 105 is electrically coupled with a corresponding third metal via V13 through a metal pad configured between them. Each sixth metal ball 106 is electrically coupled with a corresponding third signal trace T13. A plurality of seventh metal pads P17 are configured on a right bottom of the fourth circuit board B14. Each seventh metal pad P17 is electrically coupled with a corresponding fourth signal trace T14. A plurality of eighth metal pads P18 are configured on the right top of the fourth circuit board B14. Each eighth metal pad P18 is electrically coupled with a corresponding seventh metal pad P17 through a corresponding metal via configured between them. A ground metal GND is configured on a top surface of the fourth circuit board B14.

The left end of the third circuit board B13 and the left end of the fourth circuit board B14 are fixed with each other through a plurality of fourth metal balls 104, fifth metal balls 105, and sixth metal balls 106, and the right end of the fourth circuit board B14 floats, deflectable up and down. A plurality of ninth metal pads P19, a plurality of tenth metal pads P20, a plurality of eleventh metal pads P21, and a plurality of twelfth metal pads P22 are configured on a bottom surface of the fourth circuit board B14. Each ninth metal pad P11 is configured on a bottom side of a corresponding fourth metal via V14. Each tenth metal pad P12 is configured on a bottom side of a corresponding fifth metal via V15. Each eleventh metal pad P13 is configured on a bottom side of a corresponding sixth metal via V16. Each twelfth metal pad P14 is configured on a left end of a corresponding fourth signal trace T14.

FIG. 3 shows a bottom view of FIG. 2

The bottom view shows the plurality of ninth metal pads P19, tenth metal pads P20, eleventh metal pads P21, twelfth metal pads P22, the plurality of fourth signal traces T14, and the plurality of seventh metal pads P17. Each twelfth metal pad P22 is electrically coupled with a corresponding seventh metal pad P17 through a corresponding fourth signal trace T14. A ground pad GND is configured between each two seventh metal pads P17.

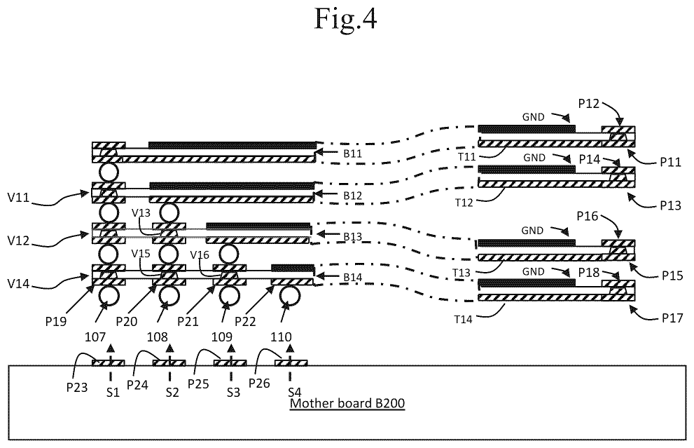

FIG. 4 shows a first application for the first embodiment according to the present invention.

A mother board B200 can be configured on a bottom side of the flexible connecting structure of FIG. 2. A plurality of seventh metal balls 107, eighth metal balls 108, ninth metal balls 109, tenth metal balls 110 are configured on a bottom of the fourth circuit board B14. The mother board B200 generates a plurality of first signals S1, second signals S2, third signals S3, and fourth signals S4. A plurality of thirteenth metal pads P23, fourteenth metal pads P24, fifteenth metal pads P25, and sixteenth metal pads P26 are configured on a top of the mother board B200.

When the mother board B200 is configured on a bottom of the flexible connecting structure, each thirteenth metal pad P23 is aligned with and electrically coupling with a corresponding seventh metal ball 107, each fourteenth metal pad P24 is aligned with and electrically coupling with a corresponding eighth metal ball 108, each fifteenth metal pad P25 is aligned with and electrically coupling with a corresponding ninth metal ball 109. Each sixteenth metal pad P26 is aligned with and electrically coupling with a corresponding tenth metal ball 110. Each first signal S1 is transmitted upward to a corresponding first signal trace T11 through a corresponding thirteenth metal pad P23. Each second signal S2 is transmitted upward to a corresponding second signal trace T12 through a corresponding fourteenth metal pad P24. Each third signal S3 is transmitted upward to a corresponding third signal trace T13 through a corresponding fifteenth metal pad P25. Each fourth signal S4 is transmitted upward to a corresponding fourth signal trace T14 through a corresponding sixteenth metal pad P26.

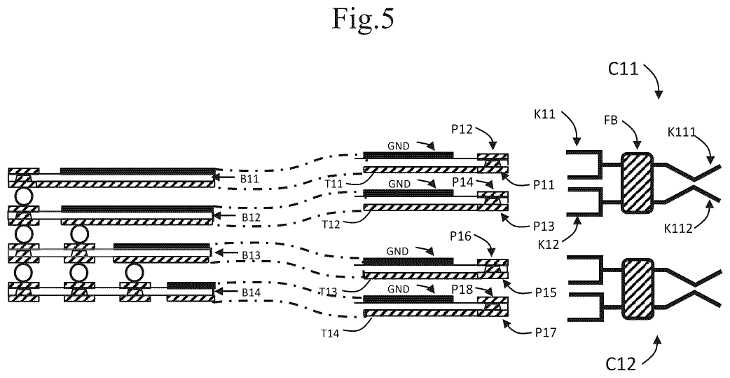

FIGS. 5˜8 show a second application for the first embodiment according to the present invention.

FIG. 5 shows a first clamp C11 and a second clamp C12 are waiting to be configured with the flexible connecting structure of FIG. 2. The first clamp C11 comprises a plurality of upper left U-shaped metal brackets K11 and a plurality of lower left U-shaped metal brackets K12 configured on a left side of a fixing body FB, a plurality of upper right V-shaped metal pins K111 and a plurality of lower right inverted V-shaped metal pins K112 configured on a right side of the fixing body FB. Each upper right V-shaped metal pin K111 is electrically coupled with a corresponding upper left U-shaped metal bracket K11. Each lower right inverted V-shaped metal pin K112 is electrically coupled with a corresponding lower left U-shaped metal bracket K12.

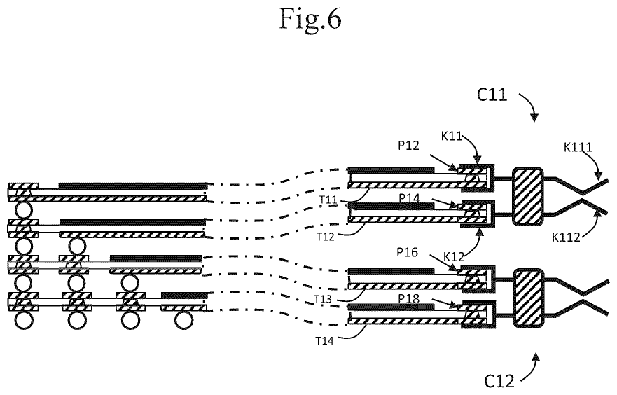

FIG. 6 shows two clamps are configured with the flexible connecting structure of FIG. 4. For the first clamp C11, each upper left U-shaped metal bracket K11 is electrically coupled with a corresponding first signal trace T11, and each lower left U-shaped metal bracket K12 is electrically coupled with a corresponding second signal trace T12 when the first clamp C11 is electrically coupled with the first circuit board B11 and the second circuit board B12. Similarly, a second clamp C12 can be configured and electrically coupled with the third circuit board B13 and the fourth circuit board B14. Totally four pluralities of signals S1, S2, S3, and S4 can be transmitted when two clamps C11, C12 are electrically coupled with the flexible connecting structure of FIG. 4.

For the first clamp C11, each upper right V-shaped metal pin K111 is electrically coupled with a corresponding first signal trace T11 for transmitting a corresponding first signal S1. Each lower right inverted V-shaped metal pin K112 is electrically coupled with a corresponding second signal trace T12 for transmitting a corresponding second signal S2. For the second clamp C12, each upper right V-shaped metal pin K113 is electrically coupled with a corresponding third signal trace T13 for transmitting a corresponding third signal S3. Each lower right inverted V-shaped metal pin K114 is electrically coupled with a corresponding fourth signal trace T14 for transmitting a corresponding fourth signal S4.

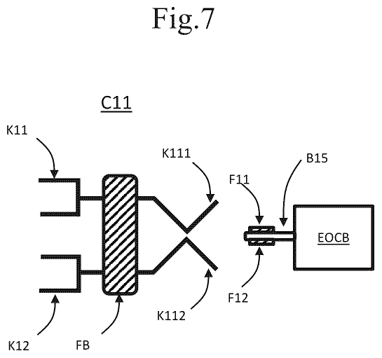

FIG. 7 shows an EOCB is waiting to be configured with the first embodiment according to the present invention.

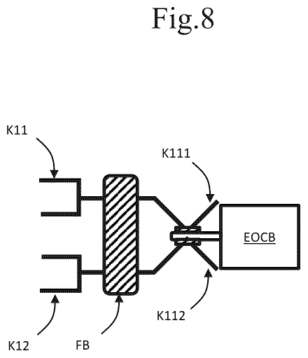

FIG. 7 shows an EOCB having an I/O circuit board B15. A plurality of top metal fingers F11 are configured on a top side of the I/O circuit board B15 and a plurality of bottom metal fingers F12 are configured on a bottom side of the I/O circuit board B15. FIG. 8 shows the EOCB is configured with the first embodiment according to the present invention. When the EOCB is inserted into the clamp C11, each top metal finger F11 of the EOCB is electrically coupled with a corresponding one upper right V-shaped metal pin K111 and each bottom metal finger F12 of the EOCB is electrically coupled with a corresponding one lower right inverted V-shaped metal pin K112.

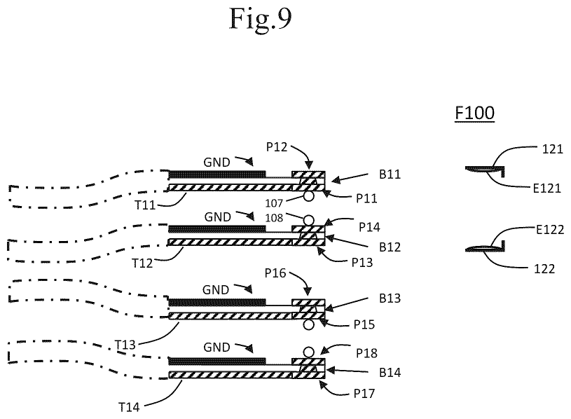

FIGS. 9˜11 shows a third application for the first embodiment according to the present invention.

FIG. 9 shows a frame is waiting to be configured with the first embodiment according to the present invention. FIG. 9 shows a plurality of seventh metal balls 107 are configured on a right bottom of the first circuit board B11, each seventh metal ball 107 is configured on a bottom surface of a corresponding first metal pad P11. A plurality of eighth metal balls 108 are configured on a right top of the second circuit board B12, each eighth metal ball 108 is configured on a top surface of a corresponding fourth metal pad P14. A frame F100 is waiting to be configured with the first embodiment according to the present invention. The frame F100 has a top plate 121 and a bottom plate 122. A top elastic element E121 is configured on a bottom side of the top plate 121. A bottom elastic E122 is configured on a top side of the bottom plate 122. The elastic element can be a spring, a rubber, or equivalent.

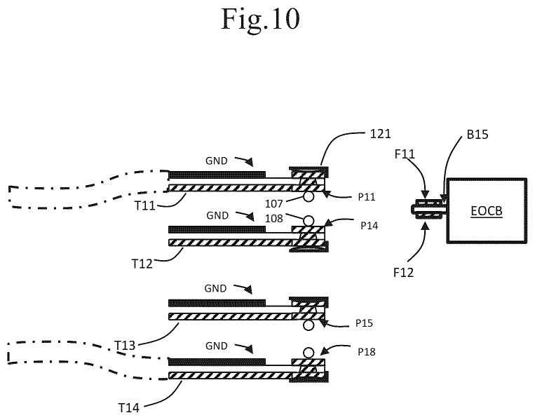

FIG. 10 shows an EOCB is waiting to be configured with the first embodiment according to the present invention. The top elastic element E121 presses against the plurality of second metal pads P12, and the bottom elastic element E122 presses against the plurality of first metal pads P11 when the frame F100 is configured with the first embodiment according to the present invention. An EOCB is waiting to be configured with the first embodiment according to the present invention.

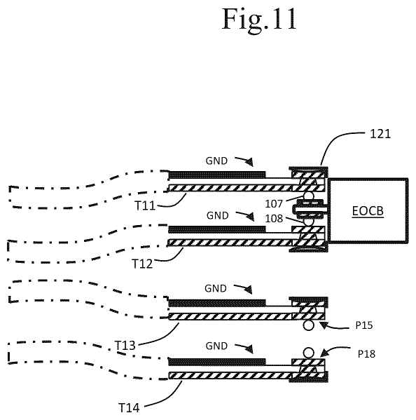

FIG. 11 shows the EOCB is configured with the first embodiment according to the present invention. Each top metal finger F11 of the EOCB is electrically coupled with a corresponding one seventh metal ball 107 and each bottom metal finger F12 of the EOCB is electrically coupled with a corresponding eighth metal ball 108 When the EOCB is electrically coupled with the first embodiment according to the present invention.

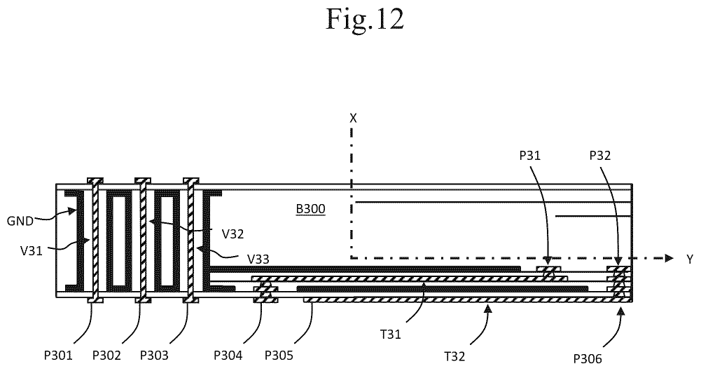

FIGS. 12˜16 show a second embodiment according to the present invention.

FIGS. 12˜13 show a process to make a rigid circuit board with a flexible portion. FIG. 12 shows a circuit board having a plurality of first coaxial metal vias V31, second coaxial metal vias V32, third coaxial metal vias V33 configured in the left of the circuit board B300. Each coaxial metal via V31, V32, V33 comprises a cylinder metal ground and a central metal, the cylinder metal ground surrounds the central metal.

A plurality of bottom first metal pads P301 are configured on a bottom side of the circuit board B300. Each first bottom metal pad P301 is electrically coupled with a central metal of a corresponding first coaxial metal via V31. A plurality of second bottom metal pads P302 are configured on a bottom side of the circuit board B300. Each second bottom metal pad P302 is electrically coupled with a central metal of a corresponding second coaxial metal via V32. A plurality of third bottom metal pads P303 are configured on a bottom side of the circuit board B300. Each third bottom metal pad P303 is electrically coupled with a central metal of a corresponding third coaxial metal via V33. A plurality of fourth bottom metal pads P304 are configured on a bottom side of the circuit board B300. Each fourth bottom metal pad P304 is electrically coupled with a corresponding first signal trace T31 through metal via or vias configured between them. A plurality of fifth bottom metal pads P305 are configured on a bottom side of the circuit board B300. Each fifth bottom metal pad P305 is electrically coupled with a corresponding second signal trace T32.

A plurality of sixth bottom metal pads P306 are configured on a right bottom side of the circuit board B300. Each sixth bottom metal pad P306 is electrically coupled with a corresponding second signal trace T32. A plurality of first signal traces T31 are longitudinally configured on a first layer of the circuit board B300. A plurality of second signal traces T32 are longitudinally configured on a second layer of the circuit board B300.

A plurality of first metal pads P31 and second metal pads P32 are configured on a third layer in the right side of the circuit board 300. FIG. 12 shows the plurality of second signal traces T32 are configured on a bottom side of the circuit board 300. The plurality of first signal traces T31 is configured above the plurality of second signal traces T32. A first metal ground GND is configured between the first signal traces T31 and the second signal traces T32. A second metal ground GND is configured above the first signal traces T31.

Each first metal pad P31 is electrically coupled with a corresponding first signal trace T31 through metal via or vias between them. Each second metal pad P32 is electrically coupled with a corresponding second signal trace T32 through metal via or vias between them. In a section view as shown in FIG. 12, material of area XY is removed through mechanical routing, cutting, laser etching, laser cutting, or chemical etching . . . etc.

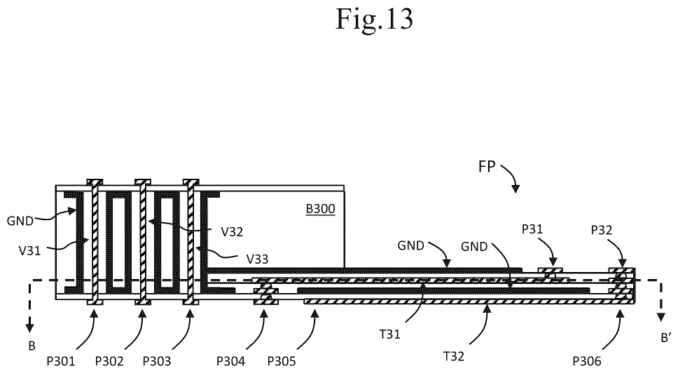

FIG. 13 shows a rigid circuit board with a flexible portion.

FIG. 13 shows a rigid circuit board B300 with a flexible portion FP after removing the material of area XY. The plurality of first metal pads P31 and the plurality of second metal pads P32 are exposed on a top side of the flexible portion FP.

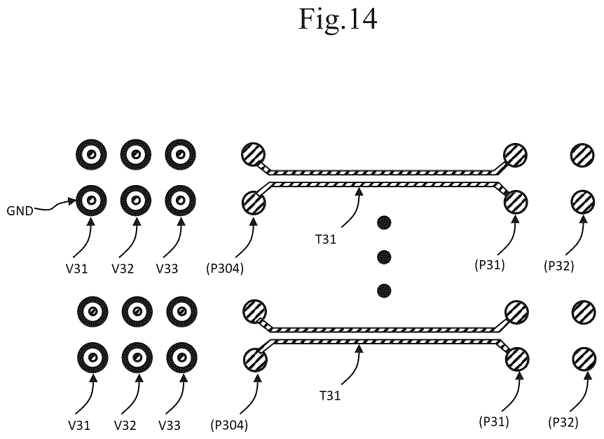

FIG. 14 shows a section view of FIG. 13 according to line BB′

The section view shows the plurality of first coaxial metal vias V31, second coaxial metal vias V32, third coaxial metal vias V33 configured in the left. The plurality of first signal traces T31 are configured in the center, and the plurality of first metal pads P31 and the second metal pads P32 are configured in the right.

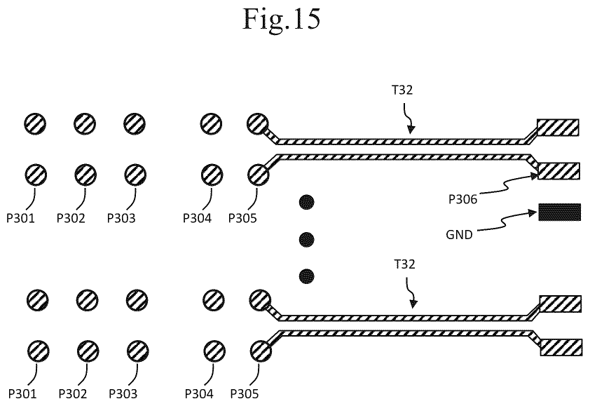

FIG. 15 shows a bottom view of FIG. 13.

FIG. 15 shows the plurality of bottom metal pads P301, P302, P303, P304, P305 configured in the left, the plurality of second signal traces T32 configured in the center, and the plurality of metal pads P306 configured in the right. A metal ground pad GND is configured between each two metal pads P306.

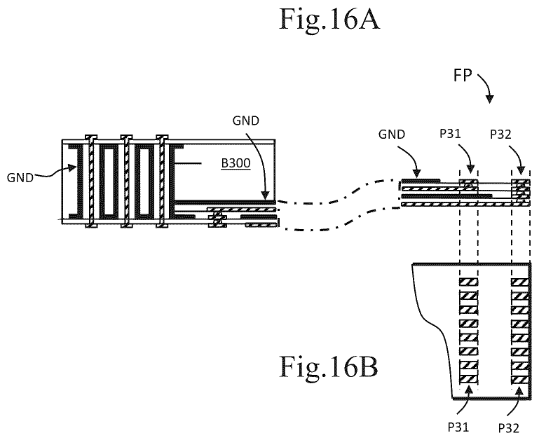

FIGS. 16A˜16B show a rigid circuit board with a flexible portion

FIG. 16A shows a rigid circuit board B300 and a flexible portion FP is configured on a right side. The flexible portion FP is deflectable up and down.

FIG. 16B shows a top view of the flexible portion FP. The plurality of first metal pads P31 and second metal pads P32 are configured on the top surface of the flexible portion FP.

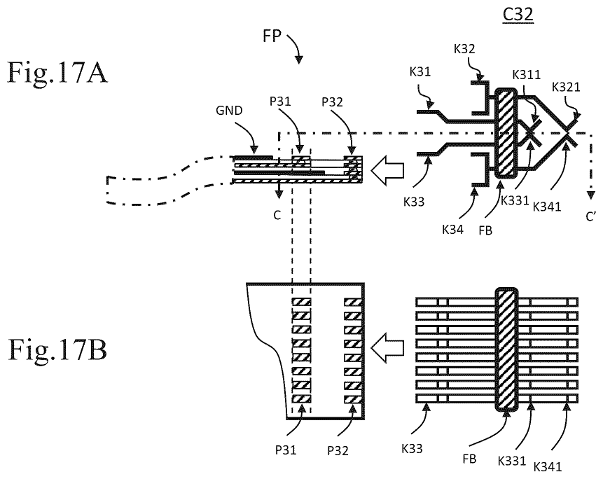

FIGS. 17˜18 show an application for the second embodiment according to the present invention.

FIGS. 17A˜17B show a clamp C32 is waiting to be configured with the flexible connecting structure of FIG. 13. FIG. 17A right figure shows a clamp C32 waiting to be configured with the flexible connecting structure of FIG. 13. The clamp C32 comprises a plurality of upper left outer metal pins K31, and a plurality of upper left inner U-shaped metal brackets K32 configured on upper left side of a fixing body FB; a plurality of lower left outer metal pins K33 and a plurality of lower left inner U-shaped metal brackets K34 configured on a lower left side of the fixing body FB; a plurality of upper right inner V-shaped metal pins K311 and a plurality of upper right outer V-shaped metal pins K321 configured on an upper right side of the fixing body FB; a plurality of lower right inner inverted V-shaped metal pins K331 and a plurality of lower right outer inverted V-shaped metal pins K341 configured on a lower right side of the fixing body.

Each upper right outer V-shaped metal pin K321 is electrically coupled with a corresponding upper left inner U-shaped metal bracket K32. Each upper right inner V-shaped metal pin K311 is electrically coupled with a corresponding upper left outer metal pin K31. Each lower right outer inverted V-shaped metal pin K341 is electrically coupled with a corresponding lower left inner U-shaped metal bracket K34. Each lower right inner inverted V-shaped metal pin K331 is electrically coupled with a corresponding lower left outer metal pin K33. FIG. 17B left figure shows a top view of FIG. 17A left figure; and FIG. 17B right figure shows a section view of FIG. 17A right figure. FIG. 17B left figure shows a top view of the flexible portion FB of the rigid circuit board B300. A plurality of first metal pads P31 and second metal pads P32 are configured on a top surface of the flexible portion FP. FIG. 17B right figure shows a section view of the clamp C32 along line CC′.

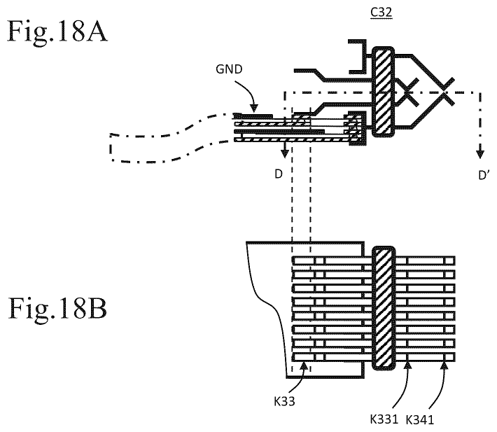

FIG. 18A shows clamp C32 electrically coupled with the flexible portion FP. Each lower left outer metal pin K33 is electrically coupled with a corresponding first metal pads P31. Each lower left inner U-shaped metal bracket K34 is electrically coupled with a corresponding second metal pads P32. FIG. 18B shows a section view along line DD′ of FIG. 18A.

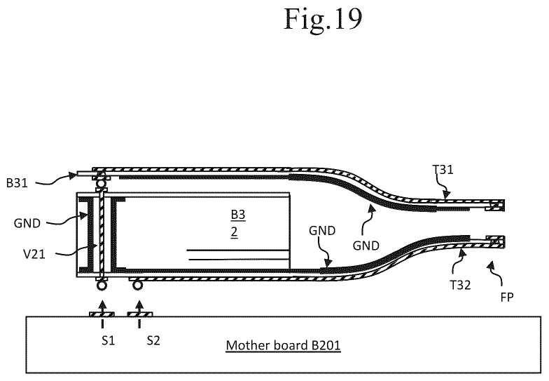

FIG. 19 shows a third embodiment according to the present invention.

FIG. 19 shows a flexible connecting structure comprises: a first circuit board B31, and a second circuit board B32. A plurality of first signal traces T31 are longitudinally configured on a top surface of the first circuit board B31. The second circuit board B32 is configured on a bottom side of the first circuit board B31. The second circuit board B32 has a flexible portion FP configured in a right side. A plurality of second signal traces T32 are longitudinally configured on a bottom surface of the second circuit board B32 and the flexible portion FP. Both the right end of the first circuit board B31 and the right end of the second circuit board B32 float, deflectable up and down. A mother board B201 can be electrically coupled with the flexible connecting structure from bottom. A plurality of first signals S1 and second signals S2 are generated from the mother board B201. Each first signal S1 can be transmitted through a corresponding first coaxial metal via V21 and a corresponding first signal trace T31. A second signal S2 generated from the mother board B201 can be transmitted through a corresponding second signal trace T32.

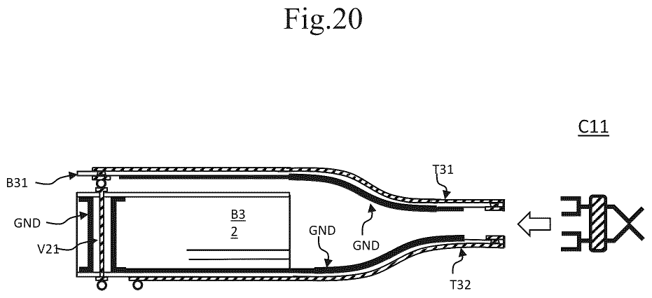

FIGS. 20˜21 show an application for the third embodiment according to the present invention.

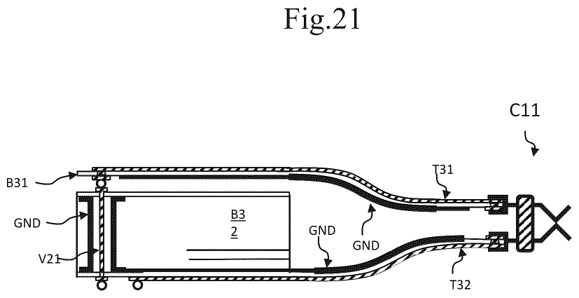

FIG. 20 shows a clamp C11 waiting to configured with the flexible connecting structure of FIG. 19. FIG. 21 shows the clamp C11 configured with the flexible connecting structure of FIG. 19. Two pluralities of signals can be transmitted from the clamp C11.

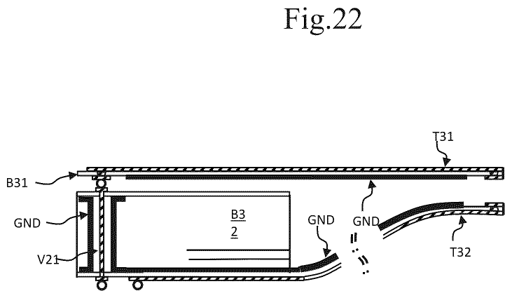

FIG. 22 shows a fourth embodiment according to the present invention.

FIG. 22 shows the first circuit board B31 can be a rigid circuit board. The right end of the second circuit board B32 can deflect up to match with the right end of the first rigid circuit board B31.

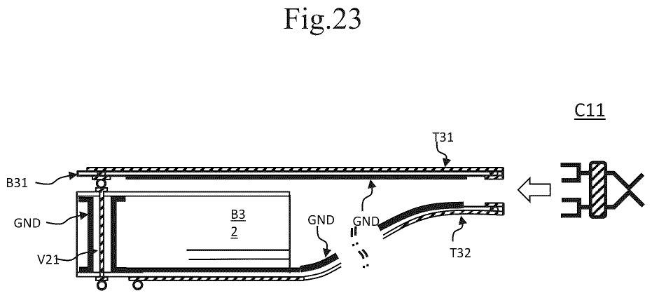

FIGS. 23˜24 show an application for the fourth embodiment according to the present invention.

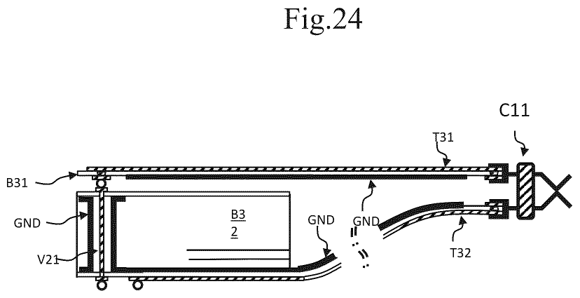

FIG. 23 shows a clamp C11 is waiting to be configured with the flexible connecting structure of FIG. 23. FIG. 24 shows the clamp C11 is configured with the flexible connecting structure of FIG. 23. Two pluralities of signals can be transmitted from the clamp C11 when the flexible connecting structure is electrically coupled with a mother board underside (not shown in FIG. 24).

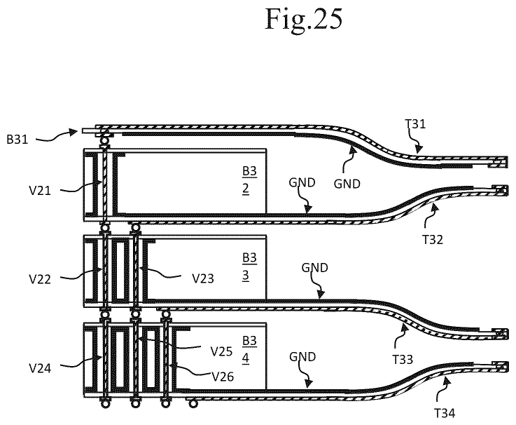

FIG. 25 shows a fifth embodiment according to the present invention.

FIG. 25 shows the flexible connecting structure comprises: a first circuit board B31, a second circuit board B32, a third circuit board B33, and a fourth circuit board B34. The second circuit board B32 is configured on a bottom side of the first circuit board B31. The third circuit board B33 is configured on a bottom side of the second circuit board B32. The fourth circuit board B34 is configured on a bottom side of the third circuit board B33.

For the first circuit board B31, a plurality of first signal traces T31 are configured on a top of the circuit board B31. For the second circuit board B32, a plurality of first coaxial metal vias V21 are configured in the left, and a plurality of second signal traces T32 are configured on a bottom of the second circuit board B32. For the third circuit board B33, a plurality of second coaxial metal vias V22 and third coaxial metal vias V23 are configured in the left. A plurality of third signal traces T33 are configured on a bottom of the third circuit board B33. For the fourth circuit board B34, a plurality of fourth coaxial metal vias V24, fifth coaxial metal vias V25, sixth coaxial metal vias V26 are configured in the left. A plurality of fourth signal traces T34 are configured on a bottom of the fourth circuit board B34. Each fourth coaxial metal via V24 is aligned with and electrically coupled with a corresponding second coaxial metal via V22. Each second coaxial metal via V22 is aligned with and electrically coupled with a corresponding first coaxial metal via V21.

Each first coaxial metal via V21 is electrically coupled with a corresponding first signal trace T31. Each fifth coaxial metal via V25 is aligned with and electrically coupled with a corresponding third coaxial metal via V23. Each third coaxial metal via V23 is electrically coupled with a corresponding second signal trace T32. Each sixth coaxial metal via V26 is electrically coupled with a corresponding third signal trace T33.

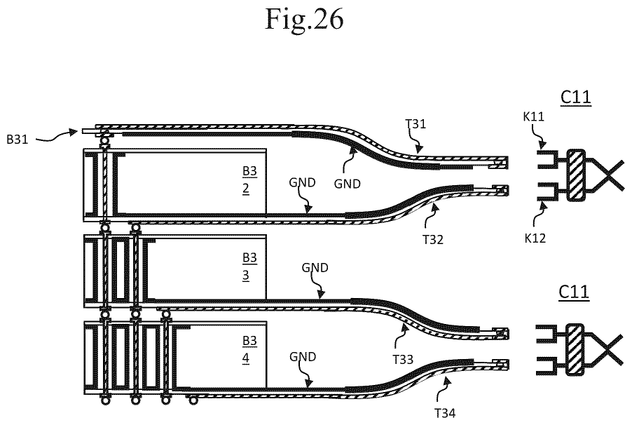

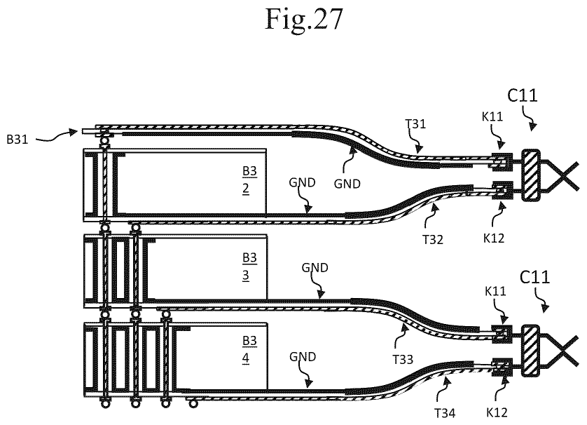

FIGS. 26-27 show an application for the fifth embodiment according to the present invention.

FIG. 26 shows two clamps C11 are waiting to configured with the flexible connecting structure of FIG. 25. FIG. 27 shows two clamps C11 are configured with the flexible connecting structure of FIG. 25. For the top clamp C11, each upper left U-shaped metal bracket K11 is electrically coupled with a corresponding first signal trace T31. Each lower left U-shaped metal bracket K12 is electrically coupled with a corresponding second signal trace T32. For the bottom clamp C11, each upper left U-shaped metal bracket K11 is electrically coupled with a corresponding third signal trace T33. Each lower left U-shaped metal bracket K12 is electrically coupled with a corresponding fourth signal trace T34.

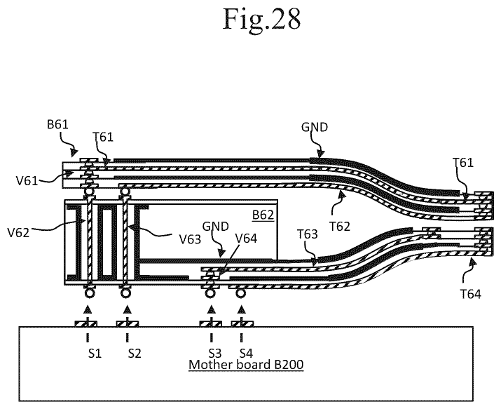

FIG. 28 shows a sixth embodiment according to the present invention.

FIG. 28 shows a flexible connecting structure comprises: a first circuit board B61 and a second circuit board B62. For the first circuit board B61, a plurality of first signal traces T61 are longitudinally configured on a first layer of the first circuit board B61, and a plurality of second signal traces T62 are longitudinally configured on a second layer of the first circuit board B61. For the second circuit board B62, a plurality of third signal traces T63 are longitudinally configured on a first layer of the second circuit board B62, and a plurality of fourth signal traces T64 are longitudinally configured on a second layer of the second circuit board B62. The second circuit board B62 is configured on a bottom side of the first circuit board B61.

The second circuit board B62 has a flexible portion FP configured in a right side. Both the right end of the first circuit board B61 and the right end of the second circuit board B62 float, bendable up and down. A mother board B200 can be electrically coupled with the flexible connecting structure from bottom. A plurality of first signals S1, second signals S2, third signals S3, and fourth signals S4 are generated from the mother board B200. When the mother board B200 is configured on a bottom side of the flexible connecting structure, each first signal S1 can be transmitted through a corresponding second coaxial metal via V62, a corresponding first metal via V61, and a corresponding first signal trace T61. Each second signal S2 can be transmitted through a corresponding third coaxial metal via V63 and a corresponding second signal trace T62. Each third signal S3 can be transmitted through a corresponding fourth metal via V64 and a corresponding third signal trace T63. Each fourth signal S4 can be transmitted through a corresponding fourth signal trace T64.

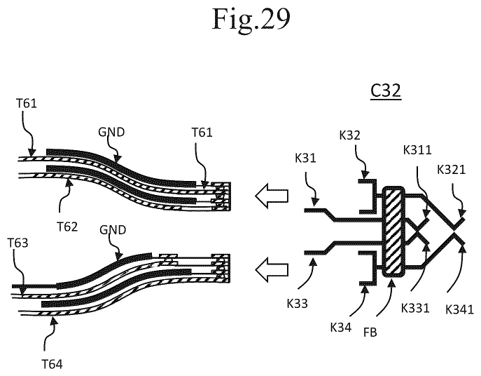

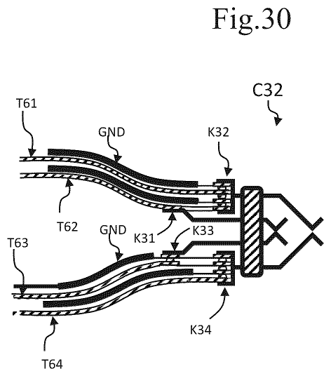

FIGS. 29-30 show an application for the sixth embodiment according to the present invention.

FIG. 29 shows a clamp C32 is waiting to be configured with the flexible connecting structure of FIG. 28. FIG. 30 shows the clamp C32 is configured with the flexible connecting structure of FIG. 28. Four pluralities of signals can be transmitted from the clamp C32 when the mother board is electrically coupled with the flexible connecting structure from bottom as shown in FIG. 28. Wherein, the upper left outer metal pin K31 is electrically coupled with a corresponding second signal trace T62. The lower left outer metal pin K33 is electrically coupled with a corresponding third signal trace T63, the upper left inner U-shaped metal bracket K32 is electrically coupled with a corresponding first signal trace T61, the lower left inner U-shaped metal bracket K34 is electrically coupled with a corresponding fourth signal trace T64.

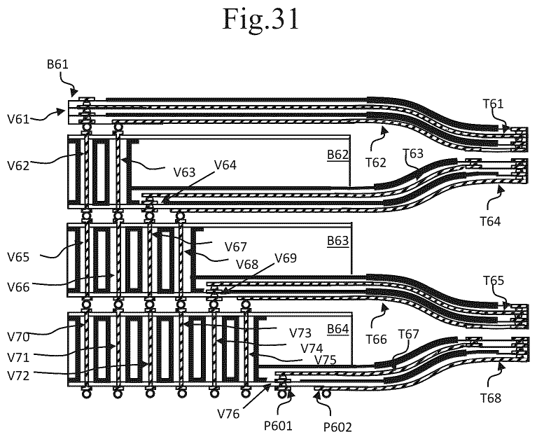

FIG. 31 shows a seventh embodiment according to the present invention.

FIG. 31 is based on the structure of FIG. 28 and adds further third circuit board B63 and fourth circuit board B64. FIG. 28 shows the first circuit board B61 and the second circuit board B62. FIG. 31 adds further third circuit board B63 and fourth circuit board B64 from bottom. The third circuit board B63 is configured on a bottom side of the second circuit board B62. A plurality of fifth coaxial metal vias V65, sixth coaxial metal vias V66, seventh coaxial metal vias V67, eighth coaxial metal vias V68, and ninth metal vias V69 are configured at a left end of the third circuit board B63. The fourth circuit board B64 is configured on a bottom side of the third circuit board B63. A plurality of tenth coaxial metal vias V70, eleventh coaxial metal vias V71, twelfth coaxial metal vias V72, thirteenth coaxial metal vias V73, fourteenth coaxial metal vias V74, fifteenth coaxial metal vias V75, and sixteen metal vias V76 are configured at a left end of the fourth circuit board B64.

Each tenth coaxial metal via V70 is aligned with and electrically coupled with a corresponding fifth coaxial metal via V65, each fifth coaxial metal via V65 is aligned with and electrically coupled with a corresponding second coaxial metal via V62, each second coaxial metal via V62 is aligned with and electrically coupled with a corresponding first metal via V61, and each first metal via V61 is electrically coupled with a corresponding first signal trace T61. Each eleventh coaxial metal via V71 is aligned with and electrically coupled with a corresponding sixth coaxial metal via V66, each sixth coaxial metal via V66 is aligned with and electrically coupled with a corresponding third coaxial metal via V63, each third coaxial metal via V63 is electrically coupled with a corresponding second signal trace T62. Each twelfth coaxial metal via V72 is aligned with and electrically coupled with a corresponding seventh coaxial metal via V67, each seventh coaxial metal via V67 is aligned with and electrically coupled with a corresponding fourth metal via V64, each fourth metal via V64 is electrically coupled with a corresponding third signal trace T63. Each thirteenth coaxial metal via V73 is aligned with and electrically coupled with a corresponding eighth coaxial metal via V68, each eighth coaxial metal via V68 is electrically coupled with a corresponding fourth signal trace T64. Each fourteenth coaxial metal via V74 is electrically coupled with a corresponding fifth signal trace T65. Each fifteenth coaxial metal via V75 is electrically coupled with a corresponding sixth signal trace T66. A plurality of first bottom metal pads P601 and second bottom metal pads P602 are configured on a bottom surface of the fourth circuit board B64.

Each first bottom metal pad P601 is electrically coupled with a corresponding seventh signal trace T67. Each second bottom metal pad P602 is electrically coupled with a corresponding eighth signal trace T68. Totally eight plurality of signals can be transmitted through the flexible connecting structure.

The left end of the second circuit board B62 and the left end of the third circuit board B63 are fixed with each other through a plurality of metal balls configured between them, and the right end of the third circuit board B63 floats, deflectable up and down. The left end of the third circuit board B63 and the left end of the fourth circuit board B64 are fixed with each other through a plurality of metal balls configured between them, and the right end of the fourth circuit board B64 floats, deflectable up and down.

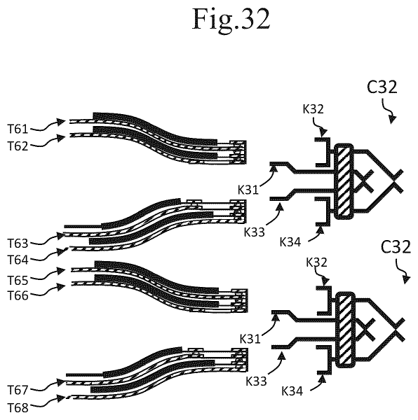

FIGS. 32-35 show an application for the seventh embodiment according to the present invention.

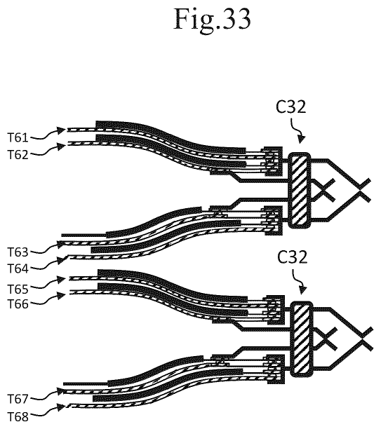

FIG. 32 shows two clamps C32 are waiting to be configured with the flexible connecting structure of FIG. 31. FIG. 33 shows the two clamps C32 are configured with the flexible connecting structure of FIG. 31. Totally eight pluralities of signals can be transmitted from the two clamps C32 when a mother board is electrically coupled with the flexible connecting structure from bottom (not shown). For the top clamp C32, the upper left outer metal pin K31 is electrically coupled with a corresponding second signal trace T62. The lower left outer metal pin K33 is electrically coupled with a corresponding third signal trace T63, the upper left inner U-shaped metal bracket K32 is electrically coupled with a corresponding first signal trace T61, the lower left inner U-shaped metal bracket K34 is electrically coupled with a corresponding fourth signal trace T64. For the bottom clamp C32, the upper left outer metal pin K31 is electrically coupled with a corresponding sixth signal trace T66. The lower left outer metal pin K33 is electrically coupled with a corresponding seventh signal trace T67, the upper left inner U-shaped metal bracket K32 is electrically coupled with a corresponding fifth signal trace T65, the lower left inner U-shaped metal bracket K34 is electrically coupled with a corresponding eighth signal trace T68.

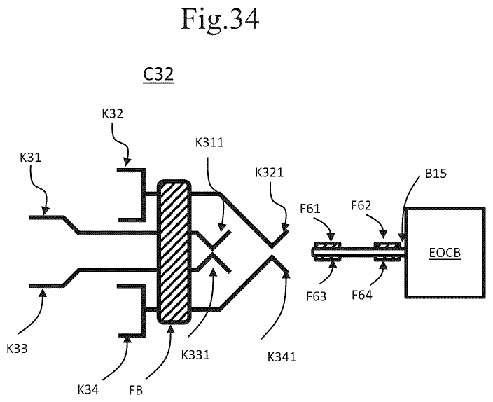

FIG. 34 shows an EOCB is waiting to be configured with a clamp C32.

FIG. 34 shows an EOCB having an I/O circuit board B15. A plurality of top first metal fingers F61 and top second metal fingers F62 are configured on a top side of the I/O circuit board B15. A plurality of bottom first metal fingers F63 and bottom second metal fingers F64 are configured on a bottom side of the I/O circuit board B15.

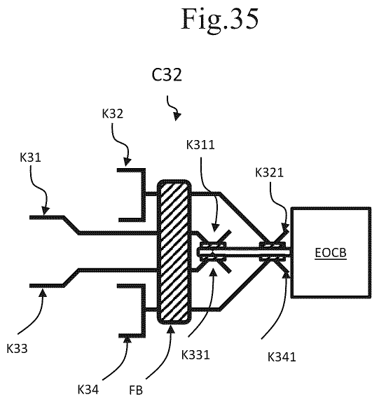

FIG. 35 shows the EOCB is configured with the clamp C32.

Each top first metal finger F61 is electrically coupled with a corresponding one upper right inner V-shaped metal pin K311. Each top second metal finger F62 is electrically coupled with a corresponding one upper right outer V-shaped metal pin K321. Each bottom first metal finger F63 is electrically coupled with a corresponding one lower right inner inverted V-shaped metal pin K331. Each bottom second metal finger F64 is electrically coupled with a corresponding one lower right outer inverted V-shaped metal pin K341.

The metal via in the embodiment can be one of plated through hole, metal filled via, and a coaxial metal via.

While several embodiments have been described by way of example, it will be apparent to those skilled in the art that various modifications may be configured without departs from the spirit of the present invention. Such modifications are all within the scope of the present invention, as defined by the appended claims.

What is claimed is:

1. A flexible connecting structure, comprises:
a first circuit board;
a plurality of first signal traces longitudinally configured on the first circuit board;
a second circuit board configured on a bottom side of the first circuit board;
a plurality of second signal traces longitudinally configured on the second circuit board; and
a plurality of first metal vias configured at a first end of the second circuit board; wherein
each first metal via is electrically coupled with a corresponding first signal trace;
the first end of the first circuit board and the first end of the second circuit board are fixed with each other through a plurality of metal balls, and the second end of the second circuit board floats, deflectable up and down.

2. The flexible connecting structure as claimed in claim 1, further comprises
a third circuit board configured on a bottom side of the second circuit board,
a plurality of third signal traces longitudinally configured on the third circuit board; and
a plurality of second and third metal vias configured at a first end of the third circuit board;
wherein
each second metal via is aligned with and electrically coupled with a corresponding first metal via, and each third metal via is electrically coupled with a corresponding second signal trace;
the first end of the second circuit board and the first end of the third circuit board are fixed with each other through a plurality of metal balls, and the second end of the third circuit board floats, deflectable up and down.

3. The flexible connecting structure as claimed in claim 2, further comprises
a fourth circuit board configured on a bottom side of the third circuit board,
a plurality of fourth signal traces longitudinally configured on the fourth circuit board; and
a plurality of fourth, fifth, and sixth metal vias configured at a first end of the fourth circuit board; wherein
each fourth metal via is aligned with and electrically coupled with a corresponding second metal via, each fifth metal via is aligned with and electrically coupled with a corresponding third metal via; each sixth metal via is electrically coupled with a corresponding third signal trace;
the first end of the third circuit board and the first end of the fourth circuit board are fixed with each other through a plurality of metal balls, and the second end of the fourth circuit board floats, deflectable up and down.

4. The flexible connecting structure as claimed in claim 1, further comprises:
a plurality of first metal pads configured on a bottom surface of the second end of the first circuit board; each first metal pad electrically coupled with a corresponding first signal trace;
a plurality of second metal pads configured on a top surface of the second end of the second circuit board; each second metal pad electrically coupled with a corresponding second signal trace;
a plurality of first metal balls, each first metal ball configured on a bottom surface of a corresponding first metal pad; and
a plurality of second metal balls, each second metal ball configured on a top surface of a corresponding second metal pad.

5. The flexible connecting structure as claimed in claim 4, further comprises:
a frame, having a top plate and a bottom plate;
a top elastic element configured on a bottom side of the top plate; and
a bottom elastic element configured on a top side of the bottom plate; wherein
the top elastic element presses against the plurality of second metal pads, and the bottom elastic element presses against the plurality of first metal pads.

6. The flexible connecting structure as claimed in claim 1, further comprises a clamp, the clamp comprises:
a plurality of upper left U-shaped metal brackets and a plurality of lower left U-shaped metal brackets configured on a left side of a fixing body; and
a plurality of upper right V-shaped metal pins and a plurality of lower right inverted V-shaped metal pins configured on a right side of the fixing body; wherein
each upper right V-shaped metal pin is electrically coupled with a corresponding upper left U-shaped metal bracket; each lower right inverted V-shaped metal pin is electrically coupled with a corresponding lower left U-shaped metal bracket; and each upper left U-shaped metal bracket is electrically coupled with a corresponding first signal trace, and each lower left U-shaped metal bracket is electrically coupled with a corresponding second signal trace when the clamp is electrically coupled with the first circuit board and the second circuit board.

7. A flexible connecting structure, comprises:
a first circuit board, a plurality of first signal traces longitudinally configured on a first layer of the first circuit board; a plurality of second signal traces longitudinally configured on a second layer of the first circuit board; a plurality of first metal vias configured at a first end of the first circuit board;
a second circuit board configured on a bottom side of the first circuit board,
a plurality of third signal traces longitudinally configured on a first layer of the second circuit board; a plurality of fourth signal traces longitudinally configured on a second layer of the second circuit board; and
a plurality of second, third, and fourth metal vias configured at a first end of the second circuit board; wherein
each first metal via electrically coupled with a corresponding first signal trace;
each third metal via is electrically coupled with a corresponding second signal trace; each fourth metal via is electrically coupled with a corresponding third signal trace; and the first end of the first circuit board and the first end of the second circuit board fixed with each other through a plurality of metal balls, and the second end of the second circuit board floats, deflectable up and down.

8. The flexible connecting structure as claimed in claim 7, further comprises
a third circuit board configured on a bottom side of the second circuit board,
a plurality of fifth signal traces longitudinally configured on a first layer of the third circuit board; a plurality of sixth signal traces longitudinally configured on a second layer of the third circuit board; a plurality of fifth, sixth, seventh, eighth, and ninth metal vias configured at a first end of the third circuit board, each fifth metal via aligned with and electrically coupled with a corresponding second metal via; each sixth metal via aligned with and electrically coupled with a corresponding third metal via; each seventh metal via aligned with and electrically coupled with a corresponding fourth metal via; and
each eighth metal via electrically coupled with a corresponding fourth signal trace; wherein the first end of the second circuit board and the first end of the third circuit board fixed with each other through a plurality of metal balls, and the second end of the third circuit board floats, deflectable up and down.

9. The flexible connecting structure as claimed in claim 8, further comprises
a fourth circuit board configured on a bottom side of the third circuit board,
a plurality of seventh signal traces longitudinally configured on a first layer of the fourth circuit board; a plurality of eighth signal traces longitudinally configured on a second layer of the fourth circuit board;
a plurality of tenth, eleventh, twelfth, thirteenth, fourteenth, fifteenth, and sixteenth metal vias configured at a first end of the fourth circuit board,
each tenth metal via aligned with and electrically coupled with a corresponding fifth metal via, each eleventh metal via aligned with and electrically coupled with a corresponding sixth metal via, each twelfth metal via aligned with and electrically coupled with a corresponding seventh metal via, each thirteenth metal via aligned with and electrically coupled with a corresponding eighth metal via,
each fourteenth metal via aligned with and electrically coupled with a corresponding ninth metal via, each fifteenth metal via electrically coupled with a corresponding sixth signal trace, and
each sixteenth metal via electrically coupled with a corresponding seventh signal trace; wherein the first end of the third circuit board and the first end of the fourth circuit board fixed with each other through a plurality of metal balls, and the second end of the fourth circuit board floats, deflectable up and down.

10. The flexible connecting structure as claimed in claim 7, further comprises a clamp, the clamp comprises:
a plurality of upper left outer metal pins and a plurality of upper left inner U-shaped metal brackets configured on upper left side of a fixing body;
a plurality of lower left outer metal pins and a plurality of lower left inner U-shaped metal brackets configured on a lower left side of the fixing body;
a plurality of upper right inner V-shaped metal pin and a plurality of upper right outer V-shaped metal pin configured on an upper right side of the fixing body;
a plurality of lower right inner inverted V-shaped metal pin and a plurality of lower right outer inverted V-shaped metal pin configured on a lower right side of the fixing body; wherein each upper right outer V-shaped metal pin is electrically coupled with a corresponding upper left inner U-shaped metal bracket; each upper right inner V-shaped metal pin is electrically coupled with a corresponding upper left outer metal pin; each lower right outer inverted V-shaped metal pin is electrically coupled with a corresponding lower left inner U-shaped metal bracket; each lower right inner inverted V-shaped metal pin is electrically coupled with a corresponding lower left outer metal pin; each upper left outer metal pin is electrically coupled with a corresponding second signal trace; each upper left inner U-shaped metal bracket is electrically coupled with a corresponding first signal trace; each lower left outer metal pin is electrically coupled with a corresponding third signal trace; each lower left inner U-shaped metal bracket is electrically coupled with a corresponding fourth signal trace.

11. The flexible connecting structure as claimed in claim 9, wherein
the signal traces are differential pair signal traces.

12. The flexible connecting structure as claimed in claim 9, wherein
the circuit board is one of a flexible circuit board and a rigid circuit board with a flexible portion; wherein
the flexible portion is made from the rigid circuit board by removing partial top material and leaving at least one layer of bottommost signal traces of the rigid circuit board.

13. The flexible connecting structure as claimed in claim 9, wherein
the metal via is one of plated through hole, metal filled via, and a coaxial metal via.

14. A clamp for transmission of Two pluralities of signals, comprises:
a plurality of upper left U-shaped metal bracket and a plurality of lower left U-shaped metal bracket configured on a left side of a fixing body,
a plurality of upper right V-shaped metal pin and a plurality of lower right inverted V-shaped metal pin configured on a right side of the fixing body, wherein
each upper right V-shaped metal pin is electrically coupled with a corresponding upper left U-shaped metal bracket; each lower inverted V-shaped metal pin is electrically coupled with a corresponding lower left U-shaped metal bracket.

15. A clamp for transmission of four pluralities of signals, comprises:
a plurality of upper left outer metal pins and a plurality of upper left inner U-shaped metal brackets configured on upper left side of a fixing body;
a plurality of lower left outer metal pins and a plurality of lower left inner U-shaped metal brackets configured on a lower left side of the fixing body;
a plurality of upper right inner V-shaped metal pin and a plurality of upper right outer V-shaped metal pin configured on an upper right side of the fixing body;
a plurality of lower right inner inverted V-shaped metal pin; and
a plurality of lower right outer inverted V-shaped metal pin configured on a lower right side of the fixing body; wherein
each upper right outer V-shaped metal pin is electrically coupled with a corresponding upper left inner U-shaped metal bracket; each upper right inner V-shaped metal pin is electrically coupled with a corresponding upper left outer metal pin; each lower right outer inverted V-shaped metal pin electrically coupled with a corresponding lower left inner U-shaped metal bracket; and each lower right inner inverted V-shaped metal pin electrically coupled with a corresponding lower left outer metal pin.

16. A rigid circuit board with a flexible portion, comprises
a rigid portion configured at a first end of the circuit board, and
a flexible portion configured at a second end of the circuit board, wherein
the flexible portion is prepared by removing partial material from a top of the rigid circuit board at a designated area so that the flexible portion comprises at least a layer of bottommost signal traces extended from the rigid portion.
